(19) United States
(12) Patent Application Publication
(10) Pub. No.: US 2004/0241917 A1
(43) Pub. Date: Dec. 2, 2004

(54) Method of forming a substrate contact for an SOI semiconductor device

(76) Inventors: Christoph Schwan, Gebhardshain (DE); Matthias Schaller, Dresden (DE); Gunter Grasshoff, Radebeul (DE)

Correspondence Address: WILLIAMS, MORGAN & AMERSON, P.C., 10333 RICHMOND, SUITE 1100, HOUSTON, TX, 77042, US

(21) Appl. No.: 10/744,331

(22) Filed: Dec. 23, 2003

(30) Foreign Application Priority Data
May 28, 2003 (DE) 103 24 433.6

(51) Int. Cl. H01L 21/84

(52) U.S. Cl. 438/151; 438/296

(57) ABSTRACT

A technique is disclosed that enables the formation of a highly conductive tungsten-containing substrate contact, wherein a lower portion of the substrate contact is formed prior to the formation of the circuit elements, and wherein an upper portion is formed along with contact plugs connecting to the circuit element in a common manufacturing process.

### BACKGROUND OF THE INVENTION

1. Field of the Invention

The present invention relates to the field of manufacture of integrated circuits, and, more particularly, to field effect transistors formed on an insulating substrate, such as silicon-on-insulator (SOI) devices, and to a method of manufacturing such devices.

2. Description of the Related Art

In modern integrated circuits, the number and, hence, the packing density of circuit elements, such as field effect transistors, is steadily increasing and, as a consequence, performance of these integrated circuits is currently improving. The increase in packing density and signal performance of integrated circuits requires the reduction of critical feature sizes, such as the gate length and, thus, the channel length of field effect transistors to minimize the chip area occupied by a single circuit element and to reduce signal propagation delay owing to a delayed channel formation. However, currently, critical feature sizes are approaching 0.1 μm and less and a further improvement in circuit performance by reducing the sizes of the transistor elements is partially offset by parasitic capacitances of the transistors formed in bulk silicon substrates.

In order to meet the ever-increasing demands with respect to device and circuit performance, circuit designers have proposed new device architectures. One technique to improve performance of a circuit, for example of a CMOS device, is to manufacture the circuit on a so-called silicon-on-insulator (SOI) substrate, wherein an insulating layer is formed on a bulk substrate, for example a silicon substrate or glass substrate, wherein the insulating layer frequently comprises silicon dioxide (also referred to as a buried oxide layer). Subsequently, a silicon layer is formed on the insulating layer in which an active region for a field effect transistor device is defined by shallow trench isolations. A correspondingly fabricated transistor is electrically entirely isolated from the regions surrounding the transistor area. Contrary to a conventional device formed on a bulk semiconductor substrate, the precise spatial confinement of the active region of the SOI device significantly suppresses parasitic effects known from conventional devices, such as latch-up and leakage currents drifting into the substrate. Moreover, SOI devices are characterized by lower parasitic capacitances compared to devices formed on a bulk semiconductor substrate and, hence, exhibit an improved high-frequency performance. Furthermore, due to the significantly reduced volume of the active region, radiation-induced charge carrier generation is also remarkably reduced and renders SOI devices extremely suitable for applications in radiation-intensive environments.

On the other hand, the advantages of SOI devices over conventionally fabricated devices may partially be offset by the so-called floating body effect, wherein the substrate of the device is not tied to a defined potential, which may lead to an accumulation of charge carriers, thereby adversely affecting the transistor characteristics, such as the threshold voltage, single transistor latch-up, and the like. Therefore, so-called substrate contacts are frequently formed to provide a connection to the substrate to drain off the excess charge.

With reference to FIGS. 1a and 1b, a typical conventional process flow for forming a substrate contact will now be described in more detail. In FIG. 1a, a semiconductor device 100 is schematically shown in a cross-sectional view. The semiconductor device 100 comprises an SOI substrate 101, which in turn includes a crystalline silicon layer 102 that is typically provided in the form of a bulk silicon substrate with an insulating layer 103 formed thereon. The insulating layer 103 may often be referred to as a buried oxide layer, since typically the insulating layer 103 may be comprised of silicon dioxide. However, the insulating layer 103 may, depending on the process for forming the SOI substrate 101, include other insulating materials, such as silicon nitride and the like. The SOI substrate 101 further includes a semiconducting layer 104 having a thickness that allows the formation of circuit elements such as field effect transistors 110a and 110b. The semiconducting layer 104 may be formed from a variety of materials, e.g., crystalline silicon, silicon-germanium, or any III-V and II-VI semiconductors in crystalline form, etc. Each of the field effect transistors 110a and 110b is enclosed by a trench isolation structure 105 that includes an insulating material, such as silicon oxide and/or silicon nitride. Thus, the field effect transistors 110a and 110b are formed on respective silicon islands that may be completely insulated from each other by the trench isolation structure 105 and the insulating layer 103. The field effect transistors 110a and 110b may include a gate electrode 111 that is separated from a channel region 113 by a gate insulation layer 112. Moreover, drain and source regions 114 may be provided within the silicon layer 104 and sidewall spacers 115 may be located at sidewalls of the gate electrode 111. The channel region 113, the drain and source regions 114 and the gate electrode 111 may comprise a dopant material with an appropriate concentration so as to provide the desired electrical performance of the transistors 110a and 110b. Moreover, metal silicide regions (not shown) may be formed on top of the source and drain regions 114 and the gate electrode 111 to minimize the resistance of these regions. The semiconductor device 100 further comprises a first dielectric layer 106 followed by a second dielectric layer 107, wherein a thickness of the second dielectric layer 107 is selected such that the transistors 110a and 110b are completely embedded within the second dielectric layer 107. The first dielectric layer 106 may be comprised of, for example, silicon oxynitride and the second dielectric layer 107 may be comprised of silicon dioxide. Typically, the composition and thickness of the first dielectric layer 106 may be selected so as to act as a bottom anti-reflective coating in a subsequent lithography process for forming contacts to the transistors 110a and 110b and to the silicon layer 102 of the SOI substrate 101. Moreover, the first dielectric layer 106 may act as an etch stop layer during the formation of the contact openings. A resist layer 108 is formed above the second dielectric layer 107 and has an opening 109 with dimensions that substantially represent the dimensions of a substrate contact opening to be formed.

A typical process flow for manufacturing the semiconductor device 100 as shown in FIG. 1a may comprise the following processes. The SOI substrate 101 may be formed by sophisticated wafer bonding techniques and may be purchased from corresponding manufacturers in a condition that allows the subsequent formation of the transistors 110a and 110b. Then, the trench isolation structure 105 may be formed by well-established photolithography, etch and deposition techniques to define a lithography resist mask, etch respective trenches, and subsequently deposit one or more insulating materials to fill the trenches, thereby forming the trench isolation structure 105. Thereafter, any excess material may be removed by chemical mechanical polishing (CMP), thereby also planarizing the substrate surface. Afterwards, the gate insulation layer 112 may be formed by sophisticated oxidation and/or deposition processes as are well known in the art. Subsequently, the gate electrode 111 may be formed by well-known lithography and etch techniques and implantation cycles may be carried out so as to form the drain and source regions 114 with a required dopant profile, wherein, depending on the process sequence used, the spacer elements 115 may be formed prior to, during or after the implantation sequence. The implanted dopants are then activated and lattice damage is cured by anneal cycles with a specified temperature and duration so as to correspond to a specified thermal budget for the formation of the transistors 110A, 110B. The thermal budget describes the integrated diffusion activity of dopants with respect to temperature and treatment duration during any heat treatments in manufacturing a transistor device. Since a well-defined dopant profile is required for the proper functionality of the transistor devices 110A, 110B, the thermal budget correspondingly restricts the temperature and/or duration of the anneal cycles, although the dopants may not be entirely activated and the lattice may not be completely recrystallized.

Then, metal silicide portions may be formed in the drain and source regions 114 and the gate electrode 111 by well-established silicidation processes. After the completion of the transistors 110a and 110b, the first dielectric layer 106 may be deposited, for instance by chemical vapor deposition (CVD), wherein a thickness and a material composition is selected so as to provide the required optical characteristics and/or the desired etch selectivity to the second dielectric layer 107 in a subsequent anisotropic etch process. Thereafter, the second dielectric layer 107 may be deposited and may be planarized by CMP to provide a substantially planar surface. Next, the resist layer 108 is formed and patterned in accordance with well-established photolithography techniques, wherein the first dielectric layer 106 may act as an anti-reflective coating.

Subsequently, an etch process sequence is performed to create a substrate contact opening in the first dielectric layer 107, the second dielectric layer 106, the trench isolation structure 105 and the insulating layer 103 which connects to the silicon layer 102. To this end, an anisotropic etch process is carried out to form an opening in the first dielectric layer 107, wherein the anisotropic etch process is substantially stopped at or within the second dielectric layer 106. Alternatively, an anisotropic etch process recipe may be used that does not exhibit a specific selectivity between the first dielectric layer 106 and the second dielectric layer 107. Then, the first dielectric layer 106 may be opened and the trench isolation structure 105 may be etched, followed by the insulating layer 103 until the etch process is stopped on or within the silicon layer 102. Thereafter, the resist layer 108 is removed, for example by plasma etching and a subsequent wet chemical clean process. The process for forming the substrate contact opening requires, in some cases, a plurality of etch procedures through a plurality of layers, thereby rendering the contact etch quite complex.

In some cases, the etch procedures are designed such that the etch stop layer 106 may provide sufficient selectivity to simultaneously form openings for contacts to the transistors 110a and/or 110b, without significantly damaging underlying device regions. However, a great burden is placed on the selective etch process after having opened the first dielectric layer 106 to form the bottom portion of the substrate contact opening so as to reliably define the corresponding contact openings and the substrate contact opening in a common etch process, thereby restricting process margins and reducing yield of the etch process.

Therefore, in other etch schemes (as shown in FIG. 1b), a further resist mask (not shown) is then formed to define respective openings for contacts to the gate electrode 111 and the drain and/or source regions 114. Thereafter, a selective anisotropic etch process is carried out to form contact openings in the second dielectric layer 107, wherein the etch process is stopped within the first dielectric layer 106, which is then opened by a subsequent selective etch step to provide a connection to the gate electrode 111 and the drain and/or source regions 114. Finally, the second resist layer is removed by, for example, a similar process as in the case of the resist layer 108 in FIG. 1a.

FIG. 1b schematically shows the semiconductor device 100 after the above-described sequence is completed. Thus, the semiconductor device 100 comprises a substrate contact opening 120, a gate contact opening 121 and, for example, one contact opening 122 connecting to the source region of the transistor 110a. Subsequently, the openings 120, 121 and 122 are filled with a highly conductive material, such as tungsten, which is presently considered as a preferred candidate for a contact metal of high-end copper-based devices due to the superior thermal stability of tungsten compared to, for example, aluminum, to connect circuit elements to further metallization layers (not shown) of the semiconductor device 100. The tungsten may be filled in by well-established deposition techniques, such as chemical and physical vapor deposition techniques. Thereafter, excess tungsten is removed by a CMP process, thereby also planarizing the substrate surface for the further processing of the device 100 so as to form one or more metallization layers.

Thus, a highly conductive contact to the substrate is achieved, requiring, however, a highly selective etch procedure for commonly defining all of the contact openings, or a complex etch scheme of at least two subsequent processes, thereby rendering the conventional approach non-efficient in view of reliability and throughput.

Due to the plurality of superior characteristics of SOI devices compared to devices formed on bulk silicon substrates and due to the availability of SOI substrates at low cost having silicon layers formed thereon with high quality, the development of SOI devices will gain in importance. Thus, an urgent need exists for an improved substrate contact technique that allows the formation of substrate contacts while eliminating or at least reducing one or more of the above-identified problems.

### SUMMARY OF THE INVENTION

Generally, the present invention is directed to a technique for forming a highly conductive substrate contact, wherein a bottom portion of the highly conductive substrate contact is formed prior to the fabrication of circuit elements, such as transistor devices and the like, and wherein an upper portion of the substrate contact is formed along with contacts connecting to a transistor device in a common etch and fill-in process.

According to one illustrative embodiment of the present invention, a method comprises the formation of a trench isolation structure in an SOI substrate and the subsequent formation of a first contact opening in the trench isolation structure, wherein the first contact opening extends through a buried insulation layer and into contact with a bulk substrate. Thereafter, the first contact opening is filled with a conductive material to form a substrate contact. Next, a circuit element is formed in an area of the SOI substrate which is enclosed by the trench isolation structure and then a second and a third contact opening are formed in a common etch procedure, wherein the second contact opening connects to the substrate contact and the third contact opening connects to the circuit element. In some embodiments, the circuit element may represent a field effect transistor, wherein the third contact opening connects to the gate electrode of the field effect transistor. In a particular embodiment, the conductive material comprises tungsten.

In accordance with another illustrative embodiment of the present invention, a method comprises determining an allowable range of temperatures and durations for a plurality of heat treatments for tungsten with respect to an interaction with silicon dioxide and silicon. Moreover, a thermal budget is established for forming a field effect transistor on an SOI substrate, wherein the thermal budget conforms to the allowable range previously determined and a tungsten-containing substrate contact is formed within a trench isolation structure that is formed in the SOI substrate. Finally, a field effect transistor is formed adjacent to the trench isolation structure in conformity with the previously established thermal budget.

According to still a further illustrative embodiment of the present invention, an SOI semiconductor device comprises a trench isolation structure enclosing a circuit element, wherein at least one substrate contact is formed within the trench isolation structure, the substrate contact having a bottom portion having a first diameter and comprising a conductive material and having a top portion having a second diameter and comprised of a conductive material, whereby the second diameter is less than the first diameter. In one particular embodiment, the bottom and top portions are comprised of tungsten.

### BRIEF DESCRIPTION OF THE DRAWINGS

The invention may be understood by reference to the following description taken in conjunction with the accompanying drawings, in which like reference numerals identify like elements, and in which:

FIGS. 1a and 1b schematically show cross-sectional views of conventional SOI transistor elements during the formation of a substrate contact;

FIGS. 2a-2g schematically show cross-sectional views of an SOI semiconductor device during various manufacturing stages in accordance with illustrative embodiments of the present invention; and

FIGS. 3a and 3b schematically show graphs for illustrating the determination of a thermal budget for the formation of the field effect transistor as shown in FIGS. 2a-2g.

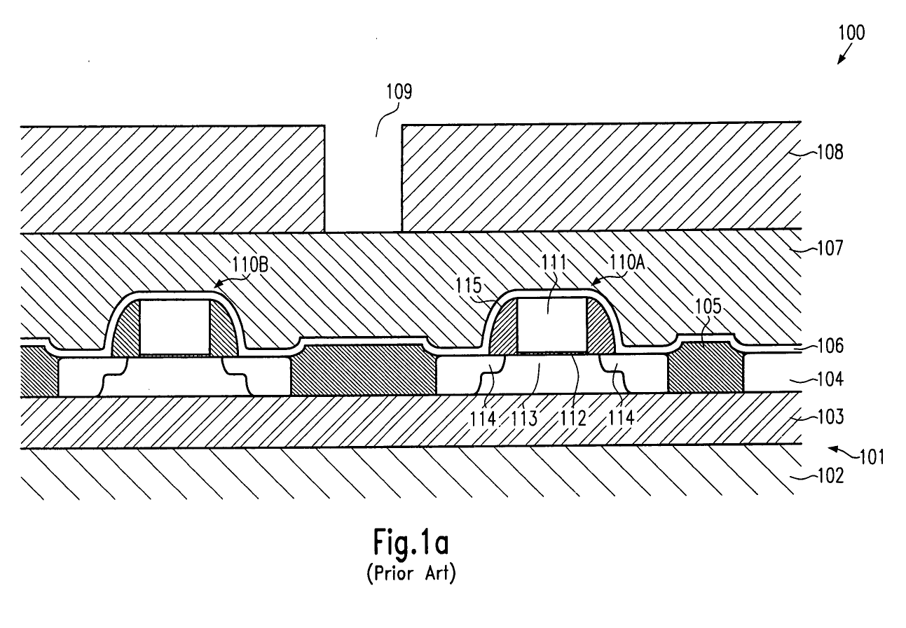

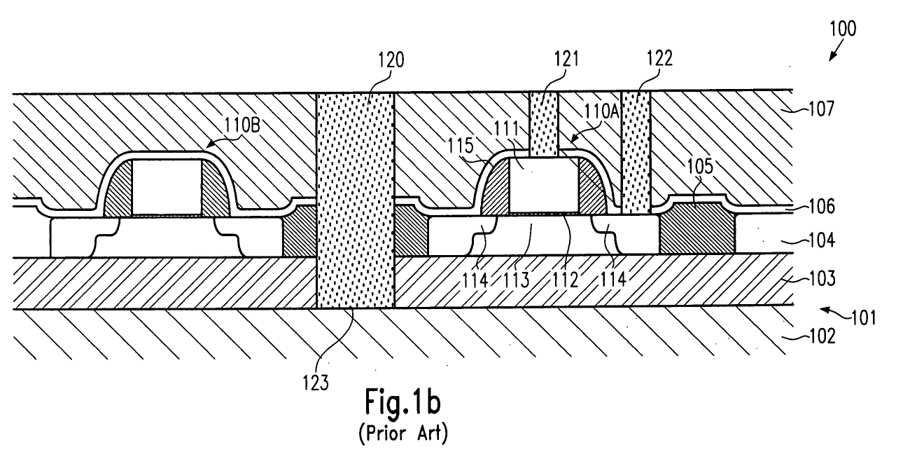

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present invention is based on the concept of exploiting the per se undesired characteristics of a typical anisotropic etch process to exhibit a structure-dependent etch rate. That is, generally, the etch rate is dependent upon the amount of etchable surface area exposed to the reactive gases within a plasma atmosphere of a dry etch process chamber. This phenomenon is frequently referred to as “loading” and may have a significant influence on the etch characteristics and has to be taken into consideration when establishing a specified etch recipe for a certain type of substrate. Moreover, it turns out that the etch rate is not only dependent on the total amount of etchable surface area but is also affected by the feature size and the pattern density provided on the substrate to be etched. For the case of contact holes, for instance, the etch rate within isolated contact holes may be significantly higher than in contact holes arranged in a dense array due to the lack of reactants in the dense contact hole array compared to the isolated contact hole. This effect is often referred to as “microloading” and requires specifically designed etch recipes regarding process parameters, such as plasma density, chamber pressure, composition of reactants, chamber geometry, and the like, so as to minimize the etch rate difference between dense and isolated features.

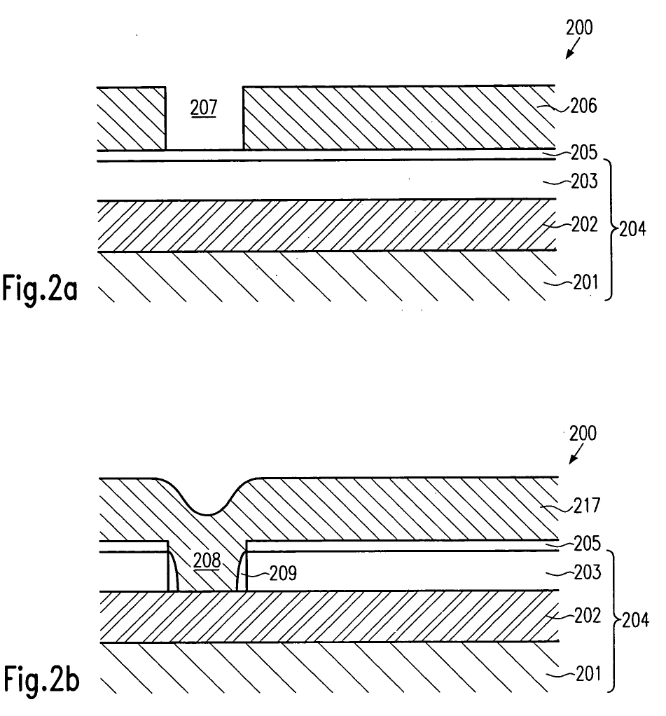

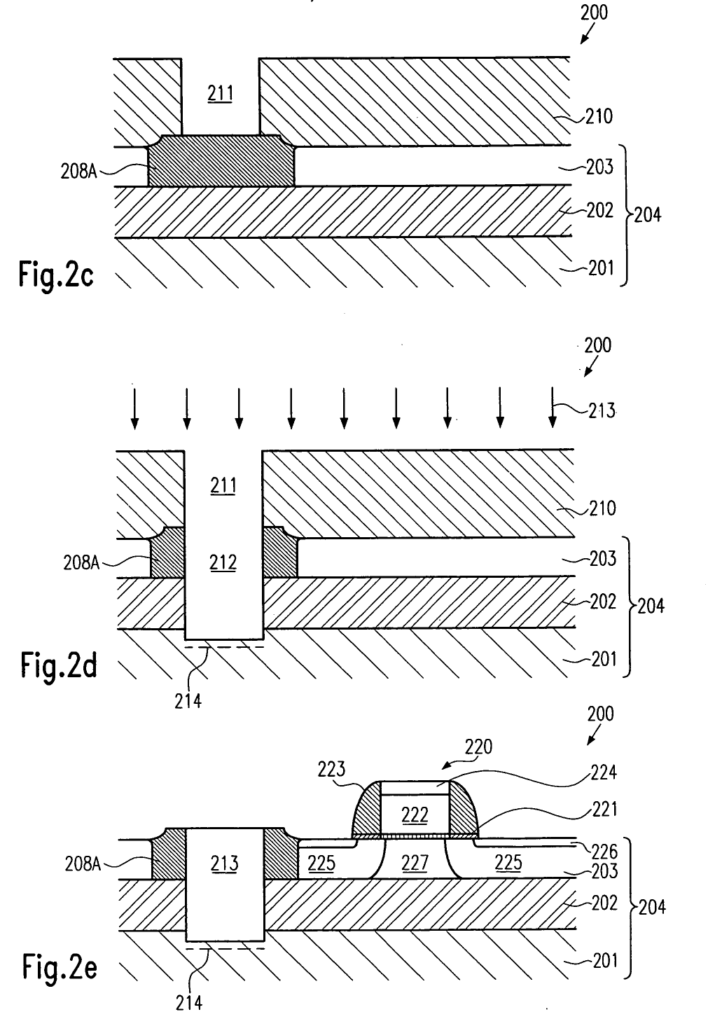

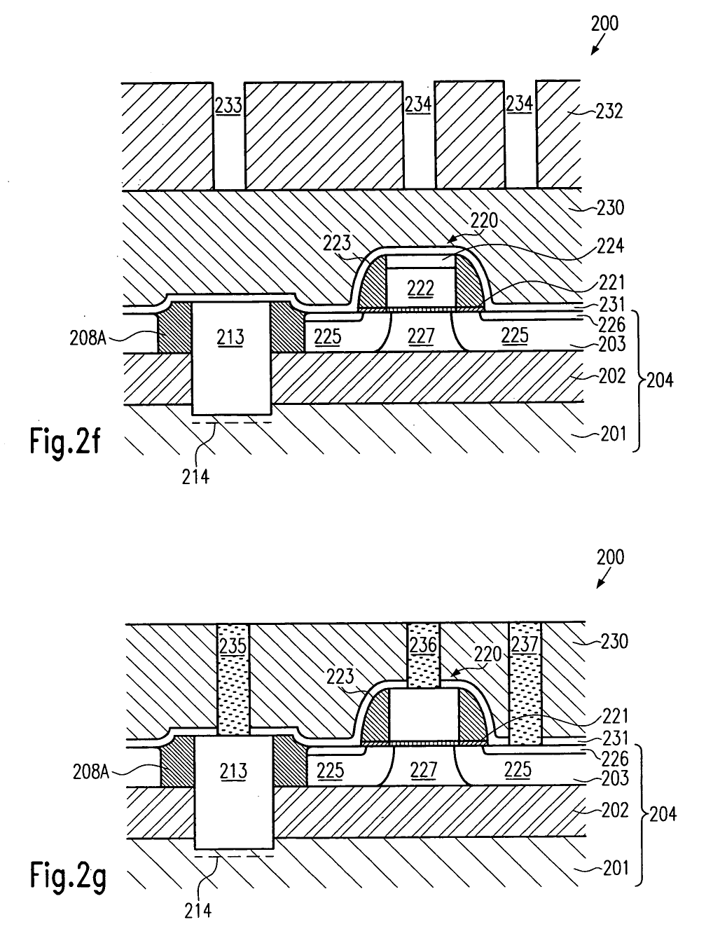

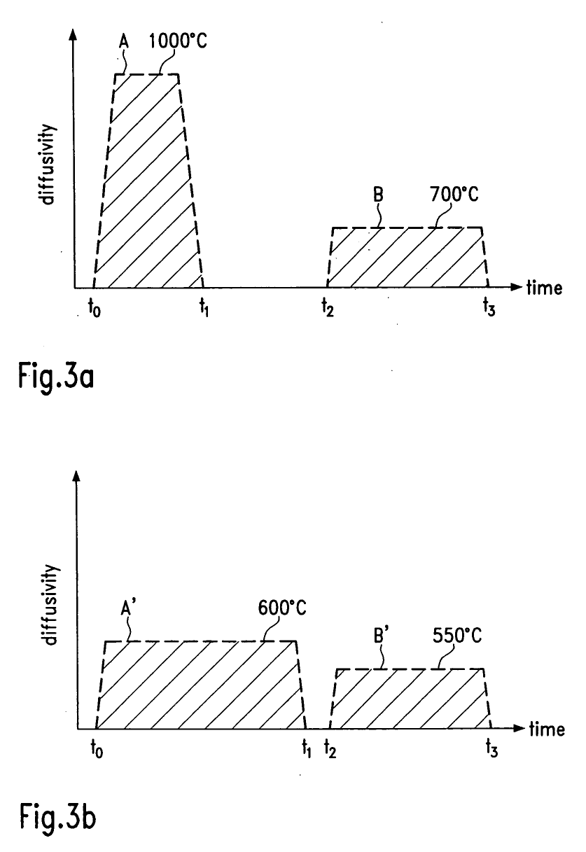

With reference to FIGS. 2a-2g and 3a-3b, further illustrative embodiments of the present invention will now be described in more detail, wherein a circuit element is represented by a field effect transistor for which the present invention is particularly useful. However, other circuit elements, such as resistors, bipolar transistors and the like, may also be used with the present invention.

In FIG. 2a, a semiconductor device 200 comprises an SOI (silicon-on-insulator) substrate 204 including a bulk substrate 201, e.g., a silicon substrate, an insulating layer 202 and an active or semiconducting layer 203. The insulating layer 202, which frequently comprises silicon dioxide and, therefore, is frequently denoted as a buried oxide layer (box), is formed on the bulk substrate 201. It should be noted, however, that the buried insulating layer 202 may, depending on the manufacturing process, contain materials other than silicon dioxide, such as silicon nitride, silicon oxynitride and the like. The active or semiconducting layer 203 is located above the buried insulating layer 202. The semiconducting layer 203 may be comprised of crystalline silicon and it may have a crystalline structure and a thickness enabling the formation of circuit elements such as a field effect transistor and the like. A CMP (chemical mechanical polishing) stop layer 205 is formed above the active layer 203 and has a thickness and a material composition that allows a reliable stop of a chemical mechanical polishing process, as will be described in more detail later on. For instance, the CMP stop layer 205 may be comprised of silicon nitride with a thin silicon dioxide layer (not shown) disposed between the active layer 203 and the silicon nitride layer. A patterned resist layer 206 is formed above the CMP stop layer 205 and includes an opening 207 with dimensions that substantially correspond to the dimensions of a trench isolation structure to be formed in the active layer 203.

The semiconductor device 200 may be formed according to the following processes. The SOI substrate 204 may be obtained by a manufacturer of semiconductor devices or may be formed by oxidizing a silicon substrate, bonding a further silicon substrate to the oxidized substrate and thinning the second silicon substrate so as to obtain the active layer 203. Preferably, the SOI substrate 204 is manufactured by forming the buried insulating layer 202 on a first silicon substrate and preparing a second silicon substrate for a so-called “smart cut” process by implanting, for instance, hydrogen atoms at a depth that substantially corresponds to the thickness of the active layer 203. After wafer bonding, the second substrate is cut at the implanted hydrogen atoms so as to obtain the high quality active layer 203 with a required thickness. Thereafter, the CMP stop layer 205 is formed; for instance by oxidizing the SOI substrate 204 and depositing a silicon nitride layer with a desired thickness. Thereafter, the resist layer 206 is formed and patterned in accordance with well-defined and well-established photolithography techniques so as to obtain the opening 207. Next, an anisotropic etch process is performed to open the CMP stop layer 205 in a first step and subsequently form an opening 208 (see FIG. 2b) in the active layer 203.

FIG. 2b schematically shows the semiconductor device 200 with an opening 208 formed in the active layer 203, wherein sidewalls of the opening 208 are covered by a silicon dioxide layer 209. Moreover, a layer of insulating material 217, for example comprised of silicon dioxide, is formed above the semiconductor device 200 so as to substantially completely fill the opening 208.

The insulating layer 217 may be formed by plasma enhanced chemical vapor deposition (PECVD), wherein the oxidized sidewall portions 209 may be formed prior to and/or after the deposition of the insulating layer 217 by exposing the semiconductor device 200 to an oxidizing ambient. When the insulating layer is comprised of silicon dioxide, the oxidation of the sidewalls of the opening 208 may alternatively be performed after the deposition of the insulating layer 217, since the oxidation is fed by oxygen diffusing through the insulating layer 217.

FIG. 2c schematically shows the semiconductor device 200 with a resist layer 210 formed above the active layer 203 and a trench isolation structure 208A, wherein an opening 211 is formed so as to expose a portion of the trench isolation structure 208A. The dimensions of the opening 211 are selected so as to substantially correspond to dimensions of a bottom portion of a substrate contact to be formed through the trench isolation structure 208A, the buried insulating layer 202 and into or in contact with the bulk substrate 201.

The semiconductor device 200 as shown in FIG. 2c may be formed in accordance with the following processes. Starting from the configuration as seen in FIG. 2b, the excess material of the insulating layer 207 may be removed by CMP, wherein the CMP stop layer 205 is designed to significantly slow down the CMP process so as to reliably remove the excess material of the insulating layer 207 without unduly affecting the active layer 203. Thereafter, the residuals of the CMP stop layer 205 are removed by a selective etch process, thereby leaving the trench isolation structure 208A substantially filled with insulating material. Next, the resist layer 210 is patterned by photolithography so as to appropriately align the opening 211 with the trench isolation structure 208A. Typically, the lateral dimension of the opening 211 is significantly less than that of the trench isolation structure 208A, thereby relaxing any concerns relating to the overlay accuracy of the opening 211 with respect to the trench isolation structure 208A. Next, an anisotropic etch process is performed to form an opening 212 (see FIG. 2d) extending through the trench isolation structure 208A, the buried insulating layer 202 into or in contact with the bulk substrate 201. Typically, the trench isolation structure 208A and the buried insulating layer 202 are substantially comprised of silicon dioxide so that well-known etch schemes may be used, wherein a selectivity to the underlying material of the bulk substrate 201, e.g., silicon, is not required, since the penetration depth into the bulk substrate 201 is not critical as long as a reliable contact to the bulk substrate 201 is assured. In some cases, actual penetration of the bulk substrate 201 may not be required in order for a reliable contact to be made to the bulk substrate 201.

FIG. 2d schematically shows the semiconductor device 200 after the completion of the above-described anisotropic etch process, in which an opening 212 has been formed having dimensions that substantially correspond to the opening 211 in the resist layer 210. Moreover, the semiconductor device 200 is shown as to be exposed to an ion implantation, indicated by 213, to locate dopants 214 within the bulk substrate 201. In this embodiment, the residual of the resist layer 210 that has not been consumed by the previously performed anisotropic etch process for creating the opening 212 may also be used as an implantation mask so as to shield the active layer 203 from the ion bombardment 213. In other embodiments, however, the residual resist layer 210 may not be considered appropriate for suitably masking the silicon layer 203, and a further resist layer (not shown) may be formed, thereby using the same photolithography mask as has been used in forming the resist layer 210. Thereby, the composition and thickness of the newly formed resist layer may be tailored to obtain an appropriate shielding effect.

The ion implantation 213 may be carried out at a dose and an energy in such a manner that the dopants 214 are placed substantially at the surface area of the bottom of the opening 212. For instance, arsenic ions may be used for the ion bombardment 213 with a dose in the range of approximately 10¹⁴-10¹⁵ atoms/cm² with an implantation energy in the range of approximately 10-50 keV. For phosphorus ions, substantially the same dose may be used, whereas the energy may range from approximately 30-100 keV. Arsenic and phosphorous may be used in case the bulk substrate 201, e.g., silicon, is slightly pre-doped by an N-type material, whereas, for example, boron may be used for a P-type pre-doped bulk substrate 201.

For boron ions, the implantation energy may be selected in the range of approximately 5-20 keV. Preferably, the ion implantation 213 is performed so as to obtain a peak concentration in the vicinity of the bottom surface of the opening 212 in the range of approximately 10¹⁹-10²⁰ atoms/cm³. A relatively high dopant concentration is advantageous in obtaining a substantially ohmic contact to the bulk substrate 201, after the opening 212 is filled with an appropriate metal. However, in other embodiments, it may be considered appropriate to select a lower concentration of the dopant 214 or even completely omit the ion implantation 213.

In a further embodiment, the dopants 214 may be introduced into the bulk substrate 201 prior to or after the formation of the opening 208 (see FIG. 2b) by performing a corresponding ion implantation process, thereby adjusting the dose and energy of the implantation process such that the atoms are injected into the bulk substrate 201 through the CMP stop layer 205, the silicon layer 203 and the buried insulating layer 202 when the implantation is carried out prior to the formation of the opening 208, and through the buried insulating layer 202 when the implantation process is carried out after the formation of the opening 208. In the latter case, the resist layer 206, already used as an etch mask for forming the opening 208, may also serve as an implantation mask in locating the dopants 214 within the bulk substrate 201.

Again referring to FIG. 2d, after removal of the resist layer 210 or the newly formed resist layer that may have served as an implantation mask, a conductive material comprised of, for example, tungsten, is deposited, for example by CVD, so as to substantially completely fill the opening 212. In some embodiments, an adhesion layer, for example comprised of titanium nitride, may conformally be deposited at least on the sidewalls of the opening 212, prior to the deposition of the tungsten, thereby significantly increasing the adhesion of tungsten to the surrounding silicon dioxide in the trench isolation structure 208A and the buried insulating layer 202. Thereafter, the excess material of the tungsten layer and possibly of the adhesion layer may be removed by etching or preferably by a CMP process.

FIG. 2e schematically shows the semiconductor device 200 with a bottom portion 213 of a substrate contact formed in the trench isolation structure 208A, the buried insulating layer 202 and partially in the bulk substrate 201, wherein the substrate contact 213 is substantially comprised of, for example, tungsten, and forms a substantially highly conductive ohmic contact to the bulk substrate 201 when the dopants 214 are provided. Adjacent to the trench isolation structure 208A, a field effect transistor 220 is formed in an area of the SOI substrate 204 that is enclosed by the trench isolation structure 208A. For convenience, only one cross-sectional view of the trench isolation structure 208A is shown. The field effect transistor 220 comprises a gate electrode 222, for example comprised of polysilicon, with a metal suicide portion 224, for instance comprised of cobalt silicide, formed on an upper portion of the gate electrode 222. A gate insulation layer 221 separates the gate electrode 222 from a lightly doped channel region 227, which, in turn, laterally separates highly doped drain and source regions 225. The drain and source regions 225 may have metal silicide portions 226, for example comprised of cobalt silicide or any other appropriate metal silicide.

A typical process flow for forming the field effect transistor 220 may comprise the following processes. After completion of the trench isolation structure 208A and the substrate contact 213, an implantation sequence may be performed so as to establish a vertical dopant profile within the active layer 203 as is required for the proper function of the field effect transistor 220. Corresponding implantation sequences are well known and well established in the art. Thereafter, the gate insulation layer 221 may be formed and subsequently the gate electrode 222 may be patterned in accordance with well-established sophisticated deposition, photolithography and etch techniques. Thereafter, the drain and source regions 225 may be formed, possibly by using sidewall spacer techniques, to establish a required vertical and lateral dopant profile. Thereafter, an anneal process is performed to activate the dopants implanted into the silicon layer 203 and to substantially re-crystallize portions of the silicon layer 203 that may have been damaged during the implantation sequences.

As previously pointed out, generally, transistor devices are manufactured with stringent process margins, for instance relating to the allowable diffusion of dopants within the silicon layer 203. The proper functionality of the field effect transistor 220 significantly depends on the vertical and lateral dopant profiles, as, for example the effective gate length, i.e., in FIG. 2e, the lateral distance between the drain and source regions 225 below the gate insulation layer 221, is defined by the location of the PN junction, formed between the channel region 227 and the drain or source region 225. Moreover, important transistor parameters, such as the threshold voltage, are defined by the vertical dopant profile (not shown) and may not be significantly varied during the diffusion of the dopant atoms. Thus, although the activation of dopant atoms and the reduction of lattice damage are important with respect to the proper device functionality, undue diffusion of the dopants is to be restricted as much as possible so as to maintain a desired dopant profile. The issue of diffusion activity of dopant atoms becomes even more exacerbated for extremely scaled transistor devices, since the shrinking transistor dimensions also require restricted process margins for vertical and lateral dopant profiles. Consequently, the field effect transistor 220 is manufactured with respect to a predefined thermal budget, which substantially describes the amount of time in which a substrate is at a particular temperature during the whole manufacturing process. The thermal budget quantifies the area under a time-temperature (t-T) curve or a time-diffusivity (t-D) curve.

FIG. 3a schematically shows a graph representing the diffusivity versus the time in the manufacturing of the field effect transistor 220, without taking into consideration the process steps for the formation of the substrate contact 213 according to the present invention. In FIG. 3a, a curve A represents the diffusivity of dopant atoms, such as the dopants in the highly doped source and drain regions 225, during the anneal cycle for activating the dopants, i.e., placing them at lattice sites, and the reduction of crystal damage. It is assumed that the anneal cycle is carried out at a temperature of approximately 1000° C. for a time interval, represented by t₀, t₁, of approximately 30 seconds. The diffusivity, herein shown in arbitrary units, may reach a maximum value within a relatively short time interval, depending on the speed of heating the SOI substrate 204 to the final anneal temperature and remains substantially constant, until the SOI substrate 204 is cooled down to temperatures well below 500° C., at which the diffusivity is assumed to be negligibly small. During a second time interval, represented by t₂, t₃, a further process of elevated temperatures, represented by a curve B, is performed, for instance during the formation of the metal silicide portions 224, 226 in accordance with a well-established silicide process sequence. Thus, an increased diffusion activity is also induced during this interval, even though the diffusivity is significantly lower than during the annealing cycle. Thus, the area under the curves A and B represents the thermal budget, except for any minor contributions of further processes carried out at lower temperatures, during the formation of the field effect transistor 220.

According to one particular embodiment of the present invention, however, the thermal processing in manufacturing the field effect transistor 220 is controlled with respect to the thermal characteristics of the tungsten in the substrate contact 213. That is, especially, the anneal cycles carried out to define the lateral and vertical dopant profiles in the drain and source regions 225 and the channel region 227 are modified to substantially correspond to the thermal budget specified for the transistor 220, wherein, however, temperature and duration of any heat treatments are modified so as to take into consideration the interaction of the tungsten with silicon and silicon dioxide. For instance, tungsten oxide may form with temperatures exceeding 400° C. and silicidation of tungsten may occur at temperatures greater than 600° C. in the presence of silicon. As is evident from FIG. 2e, the tungsten in the substrate contact 213 may be in contact, provided that no adhesion layer has been deposited, with silicon dioxide of the trench isolation structure 208A and the buried insulating layer 202, whereas the tungsten may be in contact with silicon of the bulk substrate 201 at the bottom portion of the substrate contact 213. Due to the thermal stability of the silicon dioxide, oxide formation at peripheral portions of the substrate contact 213 may be negligible, whereas a significant portion of the tungsten may be converted into tungsten silicide at the bottom of the substrate contact 213, thereby remarkably increasing the electrical resistivity. Thus, the anneal cycles in forming the field effect transistor 220 may be carried out in such a way that the predefined thermal budget is substantially maintained, whereas an undue tungsten suicide formation at the bottom of the substrate contact 213 is avoided. In one embodiment, as is schematically depicted in FIG. 3b by a curve A′, the maximum anneal temperature is selected to be approximately 600° C., while the duration of the anneal cycle, denoted as t₀, t₁, is selected so as to activate a required portion of the dopant atoms and cure lattice damage while still not exceeding the predefined thermal budget. The subsequent silicidation process, represented by a curve B, may also be modified so as to restrict the maximum temperature to approximately 550° C. so as to avoid undue tungsten silicide formation.

In a further embodiment, the interaction of the tungsten with silicon dioxide and especially with the silicon in the silicon substrate 201 is determined by measurement and/or theory for a given structure of the substrate contact 213, i.e., for predefined dimensions thereof, for a variety of temperatures and heat treatment durations to subsequently control the anneal cycles for forming the transistor 220 on the basis of the determined interaction. For instance, the increase of the electrical resistivity may be measured with respect to different temperature and heat treatment durations so as to select suitable temperatures and durations for the anneal cycle required for forming the transistor device 220. The determination of the interaction of the tungsten with the surrounding material may be performed on product substrates or may be performed on specially designed test substrates, in which, for example, the relationship between the electrical resistivity and the temperature and/or duration of a heat treatment is measured. Then, corresponding process parameters may be selected to meet the constraints posed by the thermal budget, while nevertheless creating a highly conductive substrate contact 213.

It should be noted that the activation of the dopants 214 may be carried out simultaneously with activating the dopants in the source and drain regions 225, or alternatively, a corresponding anneal cycle may be carried out prior to the formation of the transistor device 220.

Again referring to FIG. 2e, after completion of the transistor device 220, the manufacturing process is continued with the formation of a dielectric layer to embed the field effect transistor 220.

FIG. 2f schematically shows the semiconductor device 200 with an insulating layer 230, for example comprised of silicon dioxide, formed above the field effect transistor 220 and the trench isolation structure 208A, wherein an etch stop layer 231 separates the insulating layer 230 from the underlying components. The etch stop layer 231 may be comprised of silicon nitride having a composition and a thickness that provides sufficient etch selectivity so as to reliably stop an anisotropic etch process for simultaneously forming contact openings to the drain or source regions and the gate electrode of the field effect transistor 220. Contrary to the conventional approach for a three level etch process for forming a substrate contact commonly with contacts for the field effect transistor 220, the reliability of the etch stop layer 231 is significantly increased, since an upper portion of the substrate contact needs to be formed only through the insulating layer 230 as is the case for a contact to the drain or source region 225.

A resist layer 232 is formed above the insulating layer 230 and comprises a first contact opening 233 having dimensions for forming an upper portion connecting to the substrate contact 213, and second contact openings 234 having dimensions required for forming contact plugs to the field effect transistor 220.

The etch stop layer 231 and the insulating layer 230 may be formed by well-known and well-established deposition techniques, such as plasma enhanced CVD followed by a CMP process so as to planarize the surface of the insulating layer 230. Subsequently, the resist layer 232 is formed and patterned in accordance with well-known photolithography techniques, wherein, in one illustrative embodiment, the lateral dimension of the contact opening 233 is less than that of the substrate contact 213, thereby relaxing the issue of aligning the contact opening 233 with the substrate contact 213, without compromising the insulation characteristics of the trench isolation structure 208A, which may otherwise be adversely affected for a large diameter opening 233. Subsequently, a highly selective etch process is performed so as to form corresponding openings in the insulating layer 230 in a common etch procedure, wherein the etch stop layer 231 reliably stops the etch process within the layer 231 substantially without damaging any underlying substrate regions. Thereafter, the etch stop layer 231 is etched selectively to the silicide of the regions 224 and 226 as well as to the tungsten of the substrate contact 213, wherein the selectivity of the etch process with respect to the tungsten is not critical since removal of a certain amount of tungsten may be tolerated as subsequently tungsten is filled in the contact openings 233, 234. In some cases, it may be advantageous to perform the etch process for opening the etch stop layer 231 substantially without any selectivity to tungsten or preferably to tungsten oxide, so as to remove any tungsten oxide that may have formed during the deposition of the etch stop layer 231 and the insulating layer 230. In this way, an increased transition resistance to the bottom portion of the substrate contact 213 is significantly reduced.

FIG. 2g schematically shows the semiconductor device 200 with a tungsten contact plug 236 connecting to the gate electrode 222 and a tungsten contact plug 237 connecting to the source region 225. Moreover, an upper portion 235 of a tungsten contact plug connecting to the substrate contact 213 is formed in the insulating layer 230.

The tungsten plugs 235, 236, 237 are formed in a common fill process, possibly preceded by the deposition of an adhesion layer, for instance comprised of titanium nitride, wherein any excess tungsten and possibly adhesion layer material is removed by CMP.

As a result, the present invention discloses an improved technique for forming a highly conductive tungsten-containing substrate contact, wherein a lower portion is formed prior to the formation of circuit elements and wherein an upper portion is formed in a common etch and fill process so as to achieve a high degree of compatibility with a conventional substrate contact process technique.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a trench isolation structure in an SOI substrate;
forming a first contact opening in said trench isolation structure, said first contact opening extending through a buried insulation layer and to a bulk substrate;
filling said first contact opening with a conductive material to form a substrate contact;
forming a circuit element in an area of said SOI substrate enclosed by said trench isolation structure; and
forming a second and a third contact opening in a common etch process, said second contact opening connecting to said substrate contact and said third contact opening connecting to said circuit element.

2. The method of claim 1, wherein said conductive material comprises tungsten.

3. The method of claim 1, wherein said circuit element comprises a field effect transistor and said third contact opening connects to a gate electrode of said field effect transistor.

4. The method of claim 1, further comprising filling said second and third contact openings in a common fill process with a conductive material.

5. The method of claim 4, wherein said conductive material for filling said second and third contact openings comprises tungsten.

6. The method of claim 1, further comprising doping a substrate region located below said substrate contact prior to forming the substrate contact.

7. The method of claim 6, wherein forming said trench isolation structure includes:
etching a trench;
doping said substrate region; and
filling an insulating material in said trench.

8. The method of claim 6, wherein forming said substrate contact includes forming a resist mask exposing a portion of said trench isolation structure that corresponds to at least said substrate region, etching said first contact opening, implanting a dopant species into said substrate region and filling in said conductive material.

9. The method of claim 3, further comprising determining an allowable range of temperature and treatment duration for at least one heat treatment to be performed during the formation of said field effect transistor element by determining at least one property of the conductive material in contact with silicon at temperatures in the range of approximately 600° C. and 1100° C. and treatment duration ranging from approximately 10 seconds to 30 minutes prior to forming said field effect transistor element, and performing any heat treatment during the formation of said field effect transistor element at a temperature for a time interval lying within the allowable range.

10. The method of claim 9, wherein said allowable range is determined by specifying a maximum amount of a metal silicide forming during the formation of said field effect transistor element.

11. A method, comprising:
determining an allowable range of temperatures and durations for a plurality of heat treatments for tungsten in the presence of at least one of silicon and silicon dioxide;
establishing a thermal budget for forming a field effect transistor on an SOI substrate, said thermal budget conforming to said allowable range;
forming a tungsten-containing substrate contact within a trench isolation structure formed in said SOI substrate; and
forming a field effect transistor adjacent to said trench isolation structure in conformity with said thermal budget.

12. The method of claim 11, wherein forming said tungsten-containing substrate contact includes:
etching an opening into said trench isolation structure through a buried insulating layer of said SOI substrate into a silicon region;
filling said opening with a material comprising tungsten; and
removing excess material by chemical mechanical polishing.

13. The method of claim 11, further comprising:
forming an insulating layer above said field effect transistor and said substrate contact; and
forming openings to said substrate contact and at least one region of said field effect transistor in a common manufacturing sequence.

14. The method of claim 13, wherein forming said contacts to said substrate contact and to said at least one area of the field effect transistor includes:
etching an opening in said insulating layer connecting to said substrate contact and etching openings connecting to a gate electrode and to a source region of said field effect transistor, respectively, in a common selective etch procedure; and
filling said openings with a conductive material comprising tungsten and removing excess material by chemical mechanical polishing.

15. A semiconductor device, comprising:
an SOI substrate having formed thereon a circuit transistor element enclosed by a trench isolation structure;
an insulating layer, in which said transistor element is embedded; and
at least one substrate contact extending through said insulating layer, said trench isolation structure, a buried insulating layer of said SOI substrate and into contact with a bulk substrate region, wherein said substrate contact is comprised of a conductive material and comprises a lower portion having a first diameter and an upper portion having a second diameter, said second diameter being less than said first diameter.

16. The device of claim 15, wherein said bulk substrate region is comprised of silicon.

17. The device of claim 15, wherein said substrate contact is comprised of tungsten.

18. The device of claim 15, wherein said substrate contact penetrates into said bulk substrate.
